(19) United States
(12) Patent Application Publication
(10) Pub. No.: US 2009/0108419 A1
(43) Pub. Date: Apr. 30, 2009

(54) LEADFRAME FOR LEADLESS PACKAGE

(75) Inventors: HENG CHANG KUO, TAINAN COUNTY (TW); PO KAI HOU, TAINAN COUNTY (TW); CHUN YING LIN, TAINAN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHIPMOS TECHNOLOGIES INC., HSINCHU (TW)

(21) Appl. No.: 12/248,362

(22) Filed: Oct. 9, 2008

(30) Foreign Application Priority Data
Oct. 31, 2007 (TW) 096140897

(51) Int. Cl. H01L 23/495

(52) U.S. Cl. 257/666; 257/E23.031

(57) ABSTRACT

A leadframe for a leadless package comprises a plurality of package areas, a plurality of slots, a plurality of connection portions, a plurality of openings, and a tape (film). Each package area comprises a plurality of package units, each of which comprises a die pad and a plurality of leads surrounding the die pad. The plurality of slots are disposed around each of the package units. The plurality of connection portions connect the plurality of package areas. The plurality of openings are disposed on the plurality of connection portions, and are aligned with some of the plurality of slots. The tape (film) fixes the plurality of package areas, the plurality of connection portions, the plurality of die pads, and the plurality of leads in place.

### BACKGROUND OF THE INVENTION

(A) Field of the Invention

The present invention relates to a leadframe for a leadless package, and more particularly, to a leadframe used by a Quad Flat Non-leaded package (QFN).

(B) Description of the Related Art

Current trends of consumer electronics focus on minimal weight and compact size. Accordingly, the QFN package is currently being applied to the traditional leaded package, and has successfully replaced the more expensive wafer level CSP (chip scale package). The CSP has reduced the size of the package to approximately the size of the chip, but it requires fine-pitch tin ball grid arrays acting as terminals of the package so that the difficulty in manufacturing such a precision package is very high. In contrast, the QFN package is not only compact in size, low in cost, and high in yield, but can also provide advantages in coplanarity and cooling performance, especially for high-speed and power management circuits. Furthermore, the QFN package does not require any pin leads extending from the sides of its package body, and therefore offers better electrical performance than the traditional package that requires a plurality of leads extending from its sides. For example, the SO (single outline) series lead package or QFP (Quad Flat package) series lead package both require leads at their sides, and, like an antenna, the leads are likely to bring noise interference in high frequency applications.

FIG. 1 is a top view showing the semi-finished product of a conventional QFN package 10. The leadframe 12 comprises a plurality of package areas 11, each of which comprises a plurality of package units 112 arranged as an array. The saw streets 113 and 114 surround the package units 112, and a cutter can pass through these streets to divide the package units 112 into individual components. Meanwhile, the cutter cuts the supporting bars (not shown) connected to the package 111 and leadframe 12.

FIG. 2 is an illustration showing the singulation process of a conventional QFN package. A cutting blade 80 cuts the QFN package 10 along the saw streets 113 and 114 to isolate each of the package units 112, with the edge of the cutting blade 80 required to cut off the package 111 and leadframe 12 simultaneously. In general, the material of the common packages 111 is a compound of epoxy, silicon particle fillers, and hardener, and the leadframe 12 is made from a metallic alloy. The edge of the cutting blade 80 comprises resin bond and diamond dots thereon, but it cannot have good cutting performance on both the package 111 and the metallic leadframe 12. When cutting through the leadframe 12, the cutting blade 80 experiences more wear. The lifespan of the cutting blade 80 is reduced due to cutting metallic materials, and consequently the frequency of cutting tool replacement increases. If the cutting speed is decreased in order to reduce the wear of the cutting blade 80, then the units per hour (UPH) of the cutting process is reduced so that the advantage of mass production is lessened. The conventional QFN package still has aforesaid existing problems that remain to be resolved.

### SUMMARY OF THE INVENTION

One aspect of the present invention provides a leadframe for a leadless package, wherein a plurality of gaps or slots surrounding each of the package units act as sawing streets for a singulation process, thereby reducing the wear of the cutting tools and improving cutting efficiency.

Another aspect of the present invention provides a leadframe for improving production efficiency. A plurality of openings located at a plurality of connection portions of the leadframe align with sawing streets to effectively reduce the metal cutting paths of a cutting tool during a singulation process, thereby improving the production efficiency of the package manufacturing.

Yet another aspect of the present invention provides a leadframe with superior structural rigidity for a leadless package. An insulating material is filled in a plurality of openings on a plurality of connection portions of the leadframe to improve the structural integrity of the leadframe. When the leadframe is picked and placed, it can be effectively transferred without risk of damage.

In view of the above aspects, the present invention provides a leadframe for a leadless package. The leadframe comprises a plurality of package areas, a plurality of slots, a plurality of connection portions, a plurality of openings, and a tape (film). Each package area comprises a plurality of package units, each of which comprises a die pad and a plurality of leads surrounding the die pad. The plurality of slots are disposed around each of the package units. The plurality of connection portions connect the plurality of package areas. The plurality of openings are disposed on the plurality of connection portions, and are aligned with some of the plurality of slots. The tape (film) fixes the plurality of package areas, the plurality of connection portions, the plurality of die pads, and the plurality of leads in place.

### BRIEF DESCRIPTION OF THE DRAWINGS

The objectives and advantages of the present invention will become apparent upon reference to the following description and the accompanying drawings in which:

FIG. 1 is a top view showing the semi-finished product of a conventional QFN package 10;

FIG. 2 is an illustration showing the singulation process of a conventional QFN package;

FIG. 3 is a top view showing a leadframe for a leadless package in accordance with one embodiment of the present invention;

FIG. 4 is a top view showing a leadframe for a leadless package in accordance with another embodiment of the present invention; FIG. 5(a) is a top view showing a leadframe for a leadless package in accordance with a further embodiment of the present invention;

FIGS. 5(b)-5(c) are cross-sectional illustrations along the line A-A in FIG. 5(a);

FIG. 6(a) is a top view showing a leadframe for a leadless package in accordance with another embodiment of the present invention;

FIGS. 6(b)-6(c) are cross-sectional illustrations along the line B-B in FIG. 6(a); and

FIG. 7 is a schematic diagram showing openings on a connection portion of a leadframe in accordance with another embodiment of the present invention.

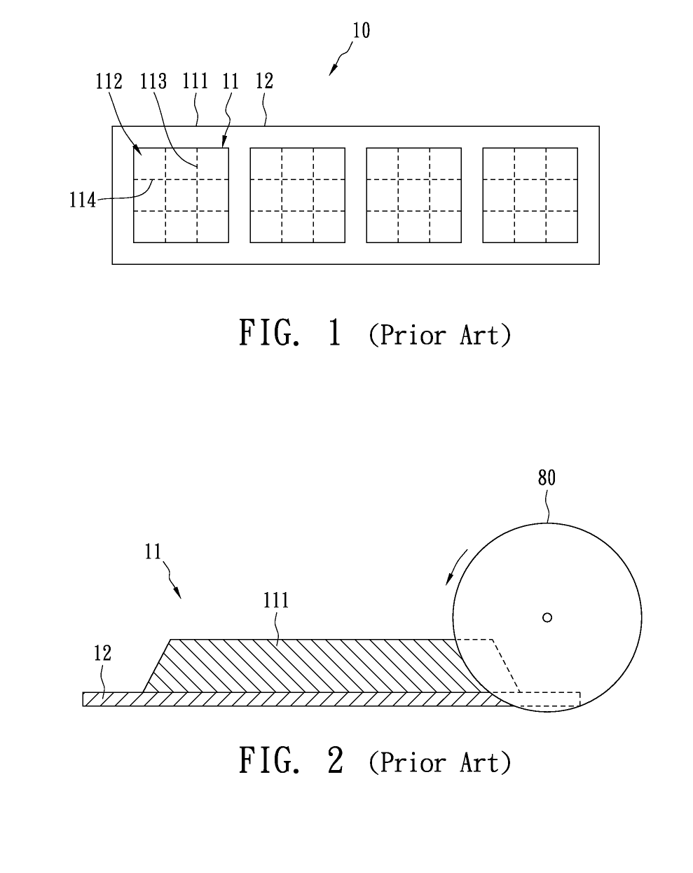

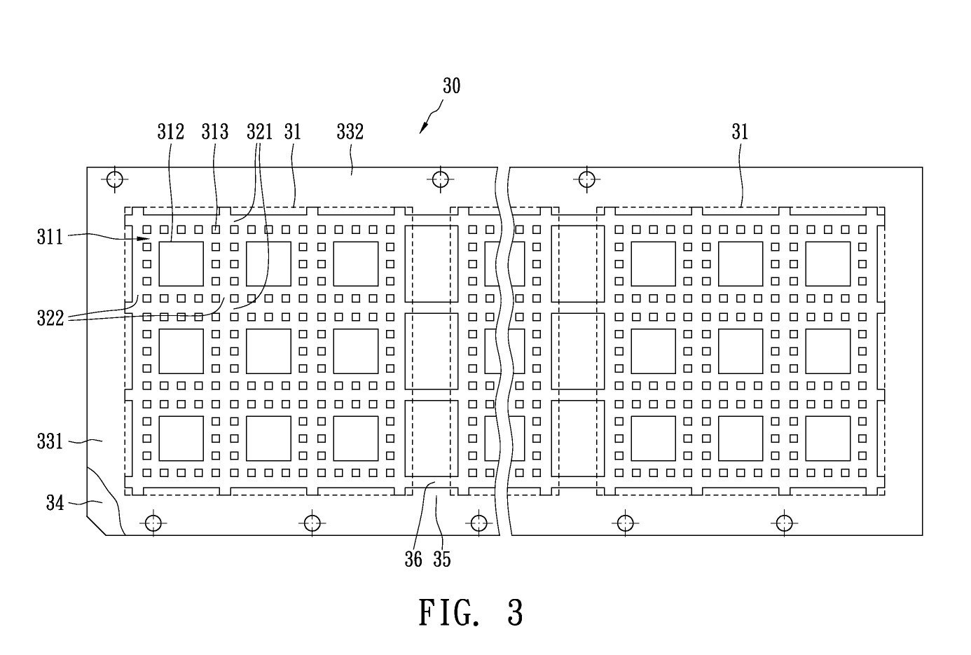

### DETAILED DESCRIPTION OF THE INVENTION

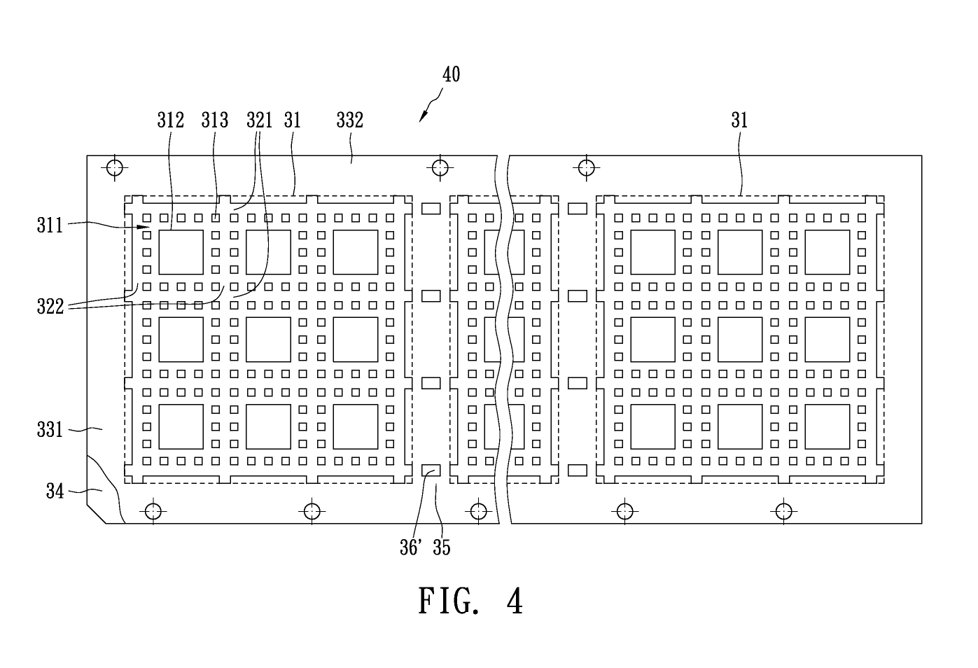

FIG. 3 is a top view showing a leadframe for a leadless package in accordance with one embodiment of the present invention. A leadframe 30 comprises a plurality of package areas 31, a plurality of first slots 321 and 322, a plurality of connection portions 35, a plurality of openings 36, and a tape (film) 34. Each of the package areas 31 comprises a plurality of package units 311 arranged in a matrix. The plurality of slots 321 and 322 surround each of the package units 311. Each of the slots 321 extends along the longitudinal direction of the leadframe 30, and is connected to one of the openings 36. Furthermore, the slots 322 extend along the transverse direction of the leadframe 30, and are connected or coupled to side rails 332. The openings 36 are disposed on the connection portions 35, and are aligned with some of the slots 321. Each of the package units 311 comprises at least one die pad 312 and leads 313 surrounding the die pad 312. The tape 34 holds the plurality of package areas 31, the plurality of connection portions 35, the plurality of side rails 311 and 332, die pads 312, and leads 313 in place.

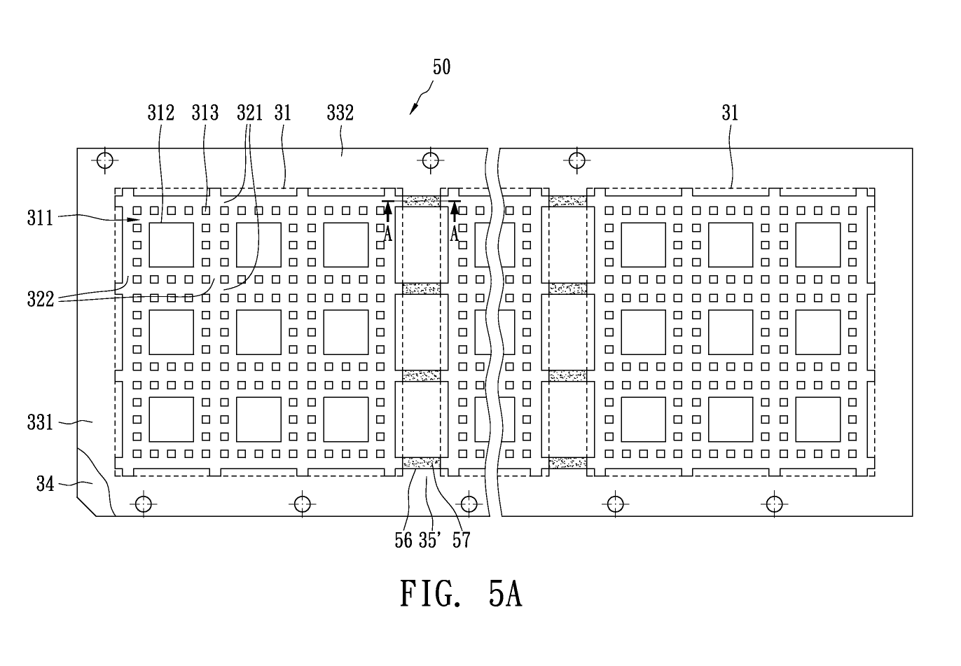

FIG. 4 is a top view showing a leadframe for a leadless package in accordance with another embodiment of the present invention. Compared with FIG. 3, the opening 36′ on the connection portions 35 of a leadframe 40 are close, and do not directly connect the slots 321. There are still metal regions of the connection portions 35 on two sides of the openings 36′. Therefore, the leadframe 40 has superior structural rigidity which reduces risk of damage during movement.

In order to consider both the structural rigidity and the production efficiency of the singulation process, the present invention further puts forth two following embodiments.

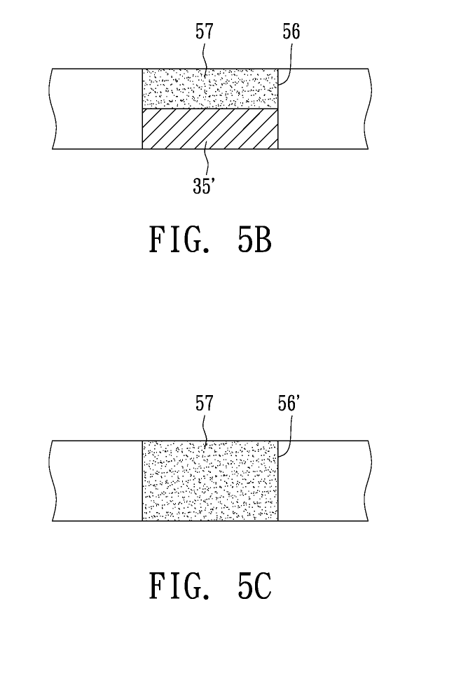

FIG. 5(a) is a top view showing a leadframe for a leadless package in accordance with a further embodiment of the present invention. A leadframe 50 comprises a plurality of package areas 31, a plurality of first slots 321 and 322, a plurality of connection portions 35′, a plurality of openings 36, and a tape (film) 34. Each of the package areas 31 comprises a plurality of package units 311 arranged in a matrix. The plurality of slots 321 and 322 surround each of the package units 31 1. Each of the slots 321 extends along the longitudinal direction of the leadframe 30, and is connected to one of the openings 56. Furthermore, the slots 322 extend along the transverse direction of the leadframe 50, and are connected or coupled to side rails 332. The openings 56 are disposed on the connection portions 35′, and are aligned with some of the slots 321. Each of the package units 311 comprises at least one die pad 312 and leads 313 surrounding the die pad 312. The tape 34 holds the plurality of package areas 31, the plurality of connection portions 35′, the plurality of side rails 311 and 332, die pads 312, and leads 313 in place.

The openings 56 of this embodiment are grooves formed on the connection portions 35′ through a half-etching process, and are filled with an insulation layer 57, as shown in FIG. 5(b). FIG. 5(b) is a cross-sectional illustration along the line A-A in FIG. 5(a). Compared with FIG. 5(b), openings 56′ in FIG. 5(c) are holes vertically through the connection portions 35′, and are also filled with the insulation layer 57.

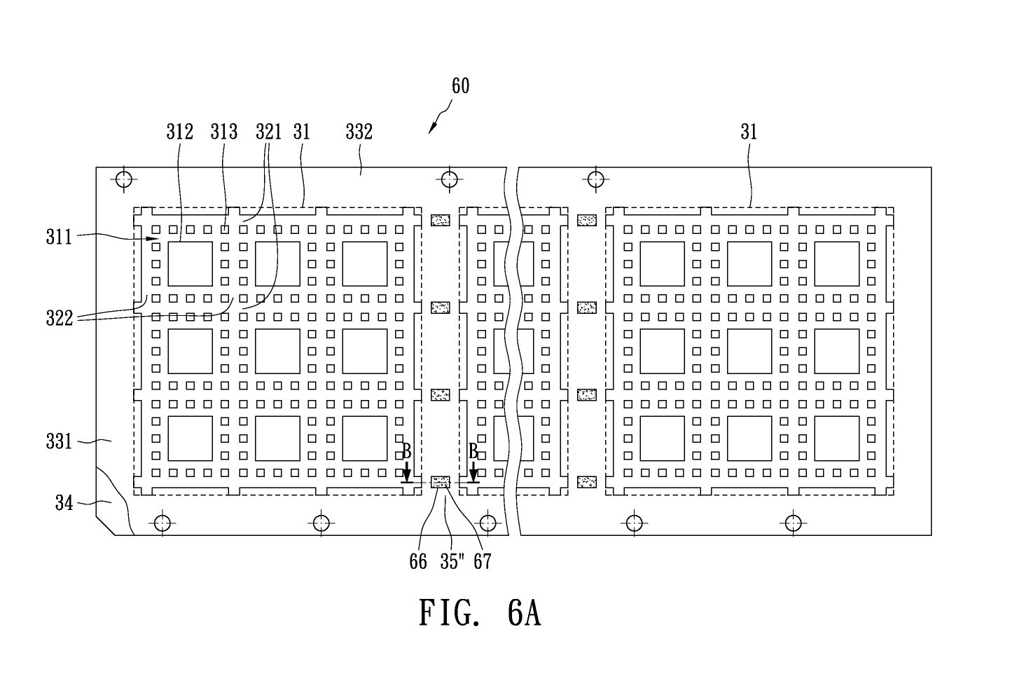

FIG. 6(a) is a top view showing a leadframe for a leadless package in accordance with one embodiment of the present invention. The openings 66 on the connection portions 35″ of a leadframe 60 are close, and do not directly connect the slots 321. Similarly, each of the openings 66 is filled with the insulation layer 67.

The openings 66 of this embodiment are grooves or blind holes formed on the connection portions 35″ through a half-etching process, and are filled with an insulation layer 57, as shown in FIG. 6(b). FIG. 6(b) is a cross-sectional illustration along the line B-B in FIG. 6(a). Compared with FIG. 6(b), openings 66′ in FIG. 6(c) are holes vertically through the connection portions 35′ and enclosed by four sidewalls. The openings 66′ are also filled with the insulation layer 67.

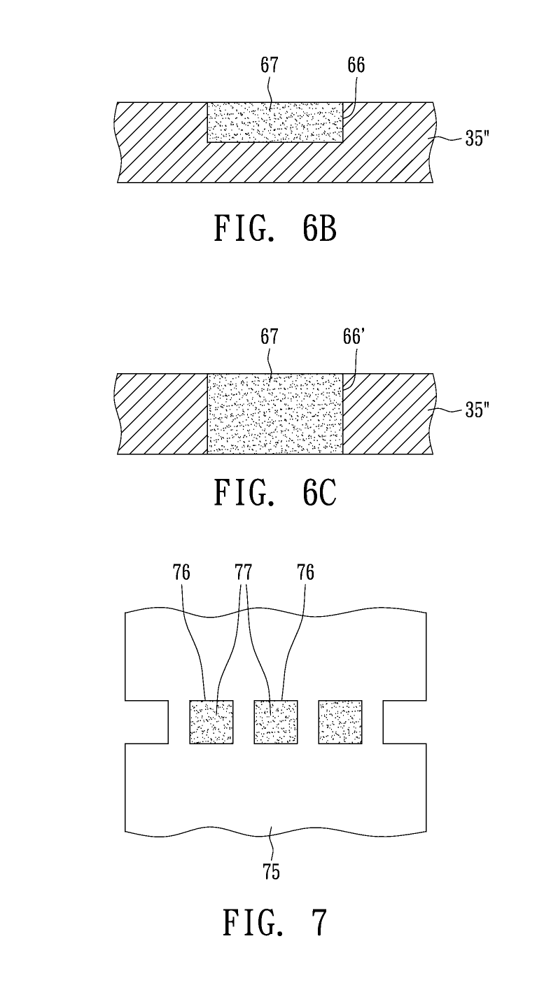

As shown by several sequentially adjacent openings 76 in FIG. 7, the openings in FIG. 6(a) can be further improved. The openings 76 can also be filled with the insulation layer 77, or kept hollow without any filler.

The above-described embodiments of the present invention are intended to be illustrative only. Numerous alternative embodiments may be devised by those skilled in the art without departing from the scope of the following claims.

What is claimed is:

1. A leadframe for a leadless package, comprising:
a plurality of package areas, each of which comprises a plurality of package units;
a plurality of slots surrounding each of the package units;
a plurality of connection portions connecting the plurality of package areas;
a plurality of openings disposed on the plurality of connection portions and aligned with some of the plurality of slots; and
a tape fixing the plurality of package areas and the plurality of connection portions.

2. The leadframe for a leadless package of claim 1, wherein each of the plurality of openings directly connects at least one of the slots.

3. The leadframe for a leadless package of claim 1, wherein two sides of each of the openings directly and respectively connect one of the slots.

4. The leadframe for a leadless package of claim 1, wherein the plurality of openings are hollow and surrounded by the side walls.

5. The leadframe for a leadless package of claim 1, further comprising a plurality of side rails surrounding the plurality of package areas.

6. The leadframe for a leadless package of claim 1, wherein each of the package units comprises a die pad and a plurality of leads surrounding the die pad.

7. The leadframe for a leadless package of claim 1, wherein the plurality of package units are arranged in a matrix.

8. The leadframe for a leadless package of claim 1, wherein the plurality of slots are extended to borders of the plurality of package units.

9. The leadframe for a leadless package of claim 1, wherein the plurality of openings vertically pass through the connection portions.

10. The leadframe for a leadless package of claim 1, wherein the plurality of openings are blind holes.

11. The leadframe for a leadless package of claim 1, further comprising an insulation layer filled in the plurality of openings.

12. The leadframe for a leadless package of claim 1, wherein several of the plurality of openings are aligned with each other, and are aligned with at least one of the slots.
